(19) United States
(12) Patent Application Publication
(10) Pub. No.: US 2025/0348002 A1
(43) Pub. Date: Nov. 13, 2025

(54) RESIST UNDERLAYER COMPOSITIONS AND METHODS OF FORMING PATTERNS USING THE COMPOSITIONS

(71) Applicant: SAMSUNG SDI CO., LTD., Yongin-si (KR)

(72) Inventors: Yoojeong CHOI, Suwon-si (KR); Ahra CHOI, Suwon-si (KR); Sungwoo JUNG, Suwon-si (KR); Hwayoung JIN, Suwon-si (KR); Seongjin KIM, Suwon-si (KR); Eunsu LEE, Suwon-si (KR); Byeong Gyu HWANG, Suwon-si (KR)

(21) Appl. No.: 19/198,295

(22) Filed: May 5, 2025

(30) Foreign Application Priority Data
May 7, 2024 (KR) 10-2024-0060124

(51) Int. Cl. G03F 7/11; H01L 21/027; H01L 21/311; H01L 21/3213

(52) U.S. Cl. CPC G03F 7/11; H01L 21/0273; H01L 21/31144; H01L 21/32139

(57) ABSTRACT

Disclosed are a resist underlayer composition, and a method of forming a photoresist pattern using the resist underlayer composition. The resist underlayer composition includes a polymer including a structural unit represented by Chemical Formula 1 or Chemical Formula 2, a compound represented Chemical Formula 3 or Chemical Formula 4, or a combination thereof, and a solvent.

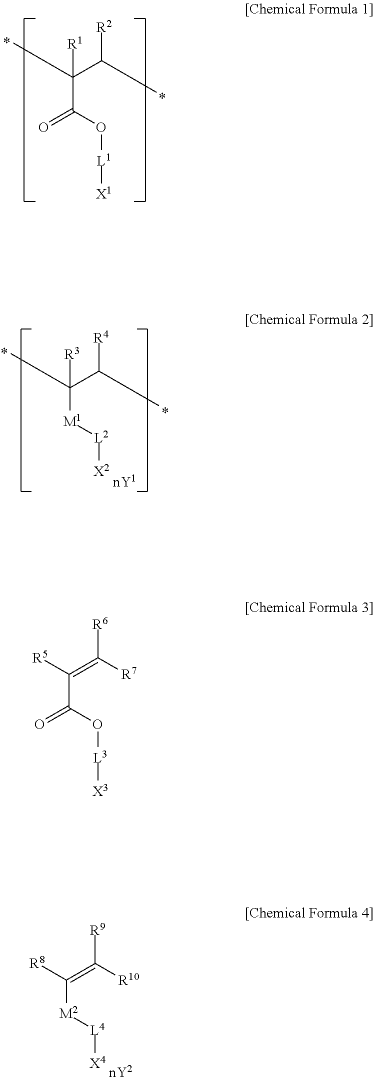

### CROSS-REFERENCE TO RELATED APPLICATION

The present application claims priority to and the benefit of Korean Patent Application No. 10-2024-0060124 filed in the Korean Intellectual Property Office on May 7, 2024, the entire content of which is hereby incorporated by reference.

### BACKGROUND

### 1. Field

The subject matter of this disclosure relates to resist underlayer compositions, and methods of forming patterns using the same.

### 2. Description of the Related Art

Recently, the semiconductor industry has developed an ultra-fine technique having a pattern of several to several tens of nanometer size. Such ultrafine technique essentially needs effective lithographic techniques.

A lithographic technique is a processing method that includes coating a photoresist film on a semiconductor substrate such as a silicon wafer to form a thin film, irradiating the photoresist film with activating radiation such as ultraviolet rays through a mask pattern on which the device pattern is drawn or formed, developing the resultant to obtain a photoresist pattern, and etching the substrate using the photoresist pattern as a protective layer to form a fine pattern corresponding to the pattern, on the surface of the substrate.

As semiconductor patterns become increasingly finer, a thickness of the photoresist layer should be thin, and accordingly, a thickness of the resist underlayer also should be thin. The resist underlayer should not collapse the photoresist pattern even if it is thin, should have good adhesion to the photoresist, and should be formed to have a uniform (or substantially uniform) thickness. The resist underlayer should have a high refractive index and low extinction coefficient for the light used in photolithography and a faster etch rate than the photoresist layer.

### SUMMARY

The resist underlayer composition according to some example embodiments of the present disclosure provides a resist underlayer having improved sensitivity to an exposure light source even in a fine patterning process, improved patterning performance and energy efficiency, and excellent adhesion to photoresist.

Some example embodiments provide a method of forming a pattern using the resist underlayer composition.

A resist underlayer composition according to some example embodiments includes a polymer including a structural unit represented by Chemical Formula 1 or Chemical Formula 2, a compound represented Chemical Formula 3 or Chemical Formula 4, or a combination thereof, and a solvent:

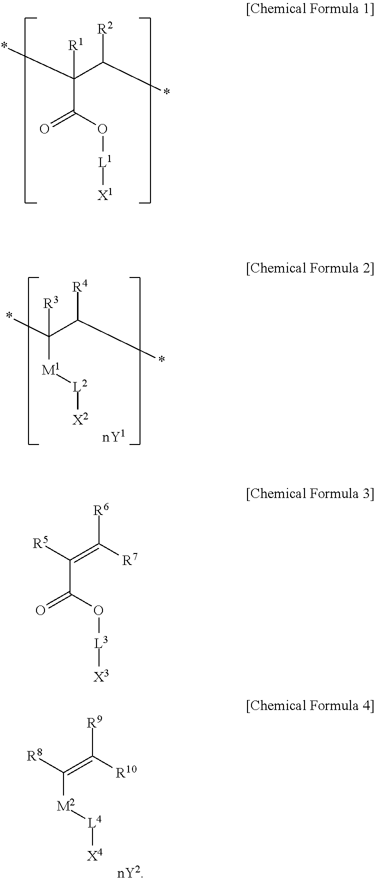

In Chemical Formula 1 to Chemical Formula 4,
R¹ to R¹⁰ are each independently hydrogen, deuterium, or a substituted or unsubstituted C1 to C10 alkyl group,
M¹ and M² are each independently a substituted or unsubstituted C1 to C10 alkylene group, —C(═O)NH—, —C(═O)—, —C(═O)O—, or a combination thereof,
L¹ to L⁴ are each independently a single bond (e.g., a single covalent bond), a substituted or unsubstituted C1 to C10 alkylene group, a substituted or unsubstituted C1 to C10 heteroalkylene group, a substituted or unsubstituted C2 to C10 heterocyclic group, or a combination thereof,
X¹ and X³ are each independently a substituted or unsubstituted C1 to C10 alkyl group, a substituted or unsubstituted C3 to C20 cycloalkyl group, or a substituted or unsubstituted C2 to C20 heterocycloalkyl group,
X² and X⁴ are each independently, —C(═O)O¹³, —S(═O)₂O^{—}, —OP(═O)O₂^{—}, or —P(═O)O₂^{—},
Y¹ and Y² are each independently a monovalent cation, and
n is 1 or 2, meaning the number of Y1 or Y2.

In Chemical Formula 1, L¹ may be a single bond (e.g., a single covalent bond) or a substituted or unsubstituted C1 to C5 alkylene group, and X¹ may be a substituted or unsubstituted C1 to C5 alkyl group, a substituted or unsubstituted C3 to C10 cycloalkyl group, or a substituted or unsubstituted C2 to C10 heterocycloalkyl group.

In Chemical Formula 2, M¹ may be a substituted or unsubstituted C1 to C5 alkylene group, —C(═O)NH—, —C(═O)O—, or a combination thereof, and Y¹ may be a monovalent cation including a nitrogen atom.

In Chemical Formula 3, L³ may be a single bond (e.g., a single covalent bond), and X³ may be a substituted or unsubstituted C1 to C10 alkyl group, or a substituted or unsubstituted C2 to C20 heterocycloalkyl group.

In Chemical Formula 4, M² may be —C(═O)NH—, or —C(═O)O—, L⁴ may be a single bond (e.g., a single covalent bond), or a substituted or unsubstituted C1 to C5 alkylene group, X⁴ may be —S(═O)₂O^{—}, —OP(═O)O₂^{—}, or —P(═O)O₂^{—}, and Y² may be a monovalent cation including a nitrogen atom.

The polymer may be represented by one or more selected from among Chemical Formula 5-1 to Chemical Formula 5-4:

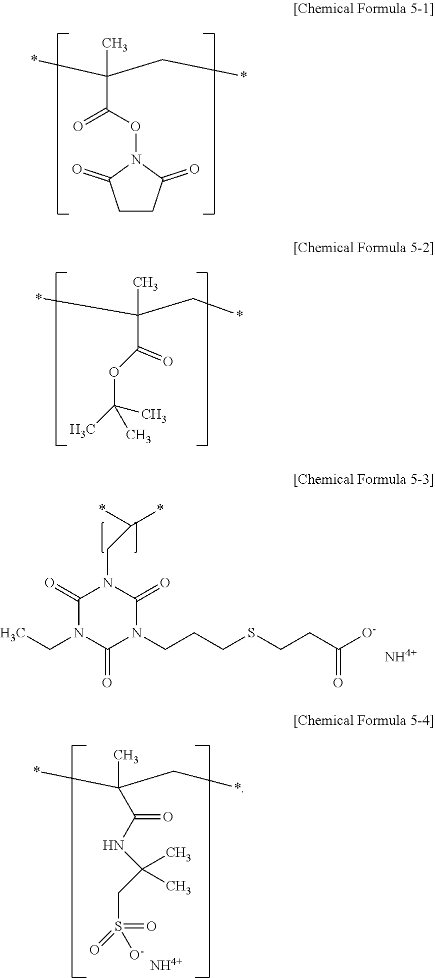

The compound may be represented by any one or more selected from among Chemical Formula 6-1 to Chemical Formula 6-5:

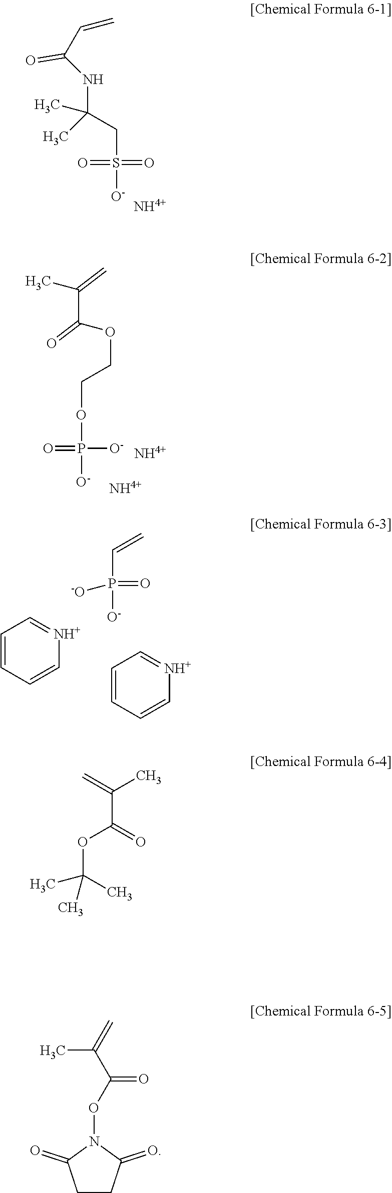

A weight average molecular weight of the polymer may be about 1,000 grams per mole (g/mol) to about 300,000 g/mol.

The structural unit represented by Chemical Formula 1 or Chemical Formula 2 may be included in an amount of about 5.0 wt % to about 80 wt % based on a total weight of the polymer.

The polymer may be included in an amount of about 0.05 wt % to about 50 wt % based on a total weight of the resist underlayer composition.

A molecular weight of the compound may be about 100 g/mol to about 1,000 g/mol.

The compound may be included in an amount of about 0.01 wt % to about 20 wt % based on a total weight of the resist underlayer composition.

The composition may further include one or more polymers selected from among an acrylic resin, an epoxy resin, a novolac-based resin, a glycoluril-based resin, and a melamine-based resin.

The composition may further include additives such as a surfactant, a thermal acid generator, a photoacid generator, a plasticizer, or a combination thereof.

According to some example embodiments, a method of forming a pattern includes forming an etching target layer on a substrate, forming a resist underlayer by applying the resist underlayer composition according to some example embodiments, forming a photoresist pattern on the resist underlayer, and sequentially etching the resist underlayer and the etching target layer using the photoresist pattern as an etching mask.

The resist underlayer composition according to some example embodiments can provide a resist underlayer having excellent storage stability and excellent adhesion to photoresist. In embodiments, even in the fine patterning process, sensitivity to the exposure light source is improved, making it possible to provide a resist underlayer having improved patterning performance and energy efficiency.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-6 are cross-sectional views illustrating a method of forming a pattern using a resist underlayer composition according to some example embodiments.

### DETAILED DESCRIPTION

Example embodiments of the present disclosure will hereinafter be described in more detail, and may be easily practiced by a person having ordinary skill in the art. However, the subject matter of this disclosure may be embodied in many different forms and is not construed as limited to the example embodiments set forth herein.

In the drawings, the thickness of layers, films, panels, regions, etc., may be exaggerated for clarity and like reference numerals designate like elements throughout the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

As used herein, if (e.g., when) a definition is not otherwise provided, “substituted” refers to replacement of a hydrogen atom of a compound by a substituent selected from deuterium, a halogen (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In embodiments, two adjacent substituents of the substituted halogen atom (F, Br, Cl, or I), hydroxy group, nitro group, cyano group, amino group, azido group, amidino group, hydrazino group, hydrazono group, carbonyl group, carbamyl group, thiol group, ester group, carboxyl group or salt thereof, sulfonic acid group or salt thereof, phosphoric acid or salt thereof, C1 to C30 alkyl group, C2 to C30 alkenyl group, C2 to C30 alkynyl group, C6 to C30 aryl group, C7 to C30 arylalkyl group, C1 to C30 alkoxy group, C1 to C20 heteroalkyl group, C3 to C20 heteroarylalkyl group, C3 to C30 cycloalkyl group, C3 to C15 cycloalkenyl group, C6 to C15 cycloalkynyl group, or C2 to C30 heterocyclic group may be fused with each other to form a ring.

As used herein, “heterocyclic group” includes a heteroaryl group, and a cyclic group including at least one heteroatom selected from N, O, S, P, and Si instead of carbon (C) of a cyclic compound such as an aryl group, a cycloalkyl group, a fused ring thereof, or a combination thereof. If (e.g., when) the heterocyclic group is a fused ring, each or entire ring of the heterocyclic group may include at least one heteroatom.

In embodiments, a substituted or unsubstituted aryl group and/or a substituted or unsubstituted heterocyclic group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted fluorenyl group, a substituted or unsubstituted dibenzofuranyl group, a substituted or unsubstituted dibenzothiphenyl group, a substituted or unsubstituted carbazolyl group, a pyridoindolyl group, a benzopyridooxazinyl group, a benzopyridothiazinyl group, a 9,9-dimethyl-9,10-dihydroacridinyl group, a combination thereof, or a combined fused ring of the foregoing groups, but are not limited thereto.

As used herein, if (e.g., when) specific definition is not otherwise provided, the term “combination” refers to mixing or copolymerization.

In embodiments, as used herein, the term “polymer” may include both oligomers and polymers.

Unless otherwise specified in the present specification, the weight average molecular weight may be measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In embodiments, unless otherwise defined in the specification, “*” indicates a linking point of a structural unit or a moiety of a polymer.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe certain elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” used herein may be interpreted as “and” or as “or” according to the context.

As used herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof” may include a mixture, a laminate, a complex, a copolymer, an alloy, a blend, a reactant of constituents.

As used herein, singular forms such as “a,” “an,” and “the” are intended to include the plural forms as well, unless the context clearly indicates otherwise.

As used herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element. Similarly, alternative language such as “or” refers to “one or more” or “some” “embodiments of the present disclosure,” each including a corresponding listed item.

In this context, “consisting essentially of” means that any additional components will not materially affect the chemical, physical, optical or electrical properties of the semiconductor film.

In the semiconductor industry, there is a constant desire or demand to reduce the size of semiconductor chips (e.g., including an integrated circuit). In order to meet this trend, a line width of the resist pattern (e.g., photoresist pattern) used in lithography technology should be reduced to a level of (e.g., at most) several tens of nanometers, and the pattern (e.g., photoresist pattern) formed in this way is used to transfer a pattern (e.g., template circuit pattern) to a lower material (e.g., a material under the pattern) by using an etching process on a lower substrate (e.g., a substrate under the pattern). However, as the pattern size of the resist (e.g., photoresist pattern) becomes smaller, a height (aspect ratio) of the resist (e.g., photoresist pattern) that can withstand or accommodate the line width is limited, and accordingly, the resist (e.g., photoresist pattern) may not have suitable or sufficient resistance in the etching step. Therefore, a resist underlayer has been used to compensate for this if (e.g., when) a thin resist material is used, if (e.g., when) the substrate to be etched is thick, or if (e.g., when) a deep pattern is required or desired.

The resist underlayer should become thinner as the thickness of the resist becomes thinner, and the photoresist pattern should not collapse even if the resist underlayer is thin. For this purpose, the resist underlayer should have excellent adhesion to the photoresist. In embodiments, in forming a thin resist underlayer, coating uniformity of the resist underlayer composition and flatness of the resist underlayer produced therefrom should be improved or enhanced, and sensitivity to the exposure light source should be improved or enhanced to improve or enhance pattern (e.g., photoresist pattern) formability and energy efficiency.

A resist underlayer composition according to some example embodiments includes a polymer including a structural unit represented by Chemical Formula 1 or Chemical Formula 2, a compound represented Chemical Formula 3 or Chemical Formula 4, or a combination thereof, and a solvent:

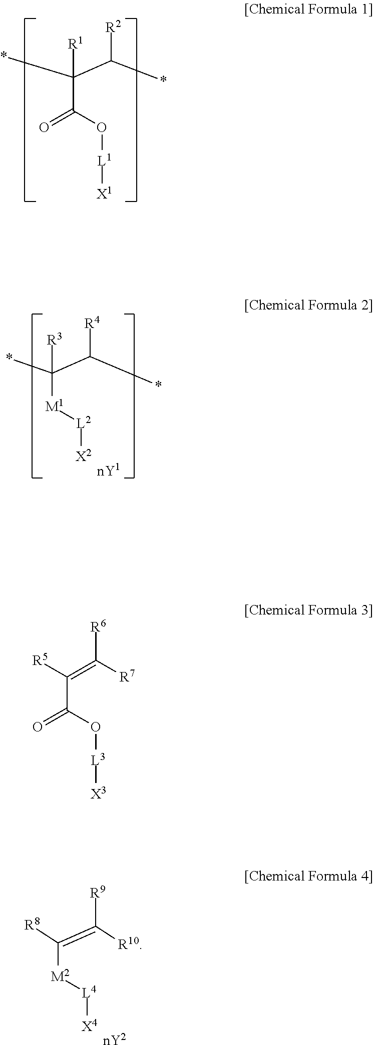

In Chemical Formula 1 to Chemical Formula 4,
R¹ to R¹⁰ may each independently be hydrogen, deuterium, or a substituted or unsubstituted C1 to C10 alkyl group,
M¹ and M² may each independently be a substituted or unsubstituted C1 to C10 alkylene group, —(═O)NH—, —C(═O)—, —C(═O)O—, or a combination thereof,
L¹ to L⁴ may each independently be a single bond (e.g., a single covalent bond), a substituted or unsubstituted C1 to C10 alkylene group, a substituted or unsubstituted C1 to C10 heteroalkylene group, a substituted or unsubstituted C2 to C10 heterocyclic group, or a combination thereof,
X¹ and X³ may each independently be a substituted or unsubstituted C1 to C10 alkyl group, a substituted or unsubstituted C3 to C20 cycloalkyl group, or a substituted or unsubstituted C2 to C20 heterocycloalkyl group,
X² and X⁴ may each independently be —C(═O)O^{—}, —S(═O)₂O^{—}, —OP(═O)O₂^{—}, or —(═O)O₂^{—},
Y¹ and Y² may each independently be a monovalent cation, and
n may be 1 or 2, meaning the number of Y¹ or Y².

The structural unit represented by Chemical Formula 1 included in the polymer and the compound represented by Chemical Formula 3 in the composition according to some example embodiments each include a terminal end group in which a hydrogen of a carboxyl group (—COOH) is substituted by a protecting group, and the structural unit represented by Chemical Formula 2 included in the polymer and the compound represented by Chemical Formula 4 respectively includes a terminal end group, which is an anionic group represented by —C(═O)O^{—}, —S(═O)₂)^{—}, —OP(═O)O₂^{—}, or —P(═O)O₂^{—} and a monovalent cation. Accordingly, the composition according to some example embodiments including the polymer and/or the compound has excellent storage stability if (e.g., when) stored, and if (e.g., when) the composition is used to form an underlayer of a photoresist film, acid (H+) is provided to the photoresist film during heat treatment and as a result, the sensitivity of the photoresist can be improved and a resist underlayer having excellent adhesion to the photoresist can be provided.

In some example embodiments, in Chemical Formula 1, L¹ may be a single bond (e.g., a single covalent bond), a substituted or unsubstituted C1 to C10 alkylene group, a substituted or unsubstituted C1 to C10 heteroalkylene group, or a combination thereof, for example, a single bond (e.g., a single covalent bond), or a substituted or unsubstituted C1 to C10 alkylene group, for example, a single bond (e.g., a single covalent bond), or a substituted or unsubstituted C1 to C5 alkylene group, but is not limited thereto.

In Chemical Formula 1, X¹ may be a substituted or unsubstituted C1to C10 alkyl group, a substituted or unsubstituted C3 to C10 cycloalkyl group, or a substituted or unsubstituted C2 to C10 heterocycloalkyl group, for example, a substituted or unsubstituted C1 to C5 alkyl group, a substituted or unsubstituted C3 to C7 cycloalkyl group, or a substituted or unsubstituted C2 to C7 heterocycloalkyl group, but is not limited thereto.

In Chemical Formula 1, R¹ and R² may each independently be hydrogen, deuterium, or a substituted or unsubstituted C1 to C5 alkyl group, for example, hydrogen, a methyl group, or an ethyl group, but are not limited thereto.

In some example embodiments, in Chemical Formula 2, M¹ may be a substituted or unsubstituted C1 to C5 alkylene group, —C(═O)NH—, —C(═O)O—, or a combination thereof, but is not limited thereto.

In Chemical Formula 2, L² may be a single bond (e.g., a single covalent bond), a substituted or unsubstituted C1 to C10 alkylene group, a substituted or unsubstituted C1 to C10 heteroalkylene group, a substituted or unsubstituted C2 to C10 heterocyclic group, or a combination thereof, for example, substituted or unsubstituted C1 to C10 heteroalkylene group, a substituted or unsubstituted C2 to C10 heterocyclic group, or a combination thereof, for example, substituted or unsubstituted C1 to C5 heteroalkylene group, a substituted or unsubstituted C2 to C10 heterocyclic group, or a combination thereof, but is not limited thereto.

In Chemical Formula 2, X² may be —C(═O)O^{—, —S(═O)}₂O^{—}, —OP(═O)O₂^{—}, or —P(═O)O₂^{—}, for example, —C(═O)O^{—}, but is not limited thereto.

In Chemical Formula 2, Y¹ may be used without limitation as long as it is a monovalent cation. For example, Y¹ is a monovalent cation including a nitrogen atom, and may be, for example, a pyridinium ion or an ammonium ion, but is not limited thereto.

In Chemical Formula 2, R³ and R⁴ may each independently be hydrogen, deuterium, or a substituted or unsubstituted C1 to C5 alkyl group, for example, hydrogen, a methyl group, or an ethyl group, but is not limited thereto.

In some example embodiments, L³ in Chemical Formula 3 may be a single bond (e.g., a single covalent bond), or a substituted or unsubstituted C1 to C10 alkylene group, for example, a single bond (e.g., a single covalent bond), but is not limited thereto.

In Chemical Formula 3, X³ may be a substituted or unsubstituted C1 to C10 alkyl group, a substituted or unsubstituted C3 to C10 cycloalkyl group, or a substituted or unsubstituted C2 to C20 heterocycloalkyl group, for example, substituted or unsubstituted C1 to C10 alkyl group, or a substituted or unsubstituted C2 to C10 heterocycloalkyl group, but is not limited thereto.

In Chemical Formula 3, R⁵ to R⁷ may each independently be hydrogen, deuterium, or a substituted or unsubstituted C1 to C5 alkyl group, for example, hydrogen, a methyl group, or an ethyl group, but are not limited thereto.

In some example embodiments, in Chemical Formula 4, M² may be −C(═O)NH—, or —C(═O)O—, but is not limited thereto.

In Chemical Formula 4, L⁴ may be a single bond (e.g., a single covalent bond), a substituted or unsubstituted C1 to C10 alkylene group, a substituted or unsubstituted C1 to C10 heteroalkylene group, for example, a single bond (e.g., a single covalent bond), or a substituted or unsubstituted C1 to C10 alkylene group, for example, a single bond (e.g., a single covalent bond) or a substituted or unsubstituted C1 to C5 alkylene group, but is not limited thereto.

In Chemical Formula 4, X⁴ may be —C(═O)O^{—, —S(═O)}₂O^{—}, —OP(═O)O₂^{—}, or —P(═O)O₂^{—}, for example, —S(═O)₂P^{—}, —OP(═O)O₂^{—}, or —P(═O)O₂^{—}, but is not limited thereto.

In Chemical Formula 4, R⁸ to R¹⁰ may each independently be hydrogen, deuterium, or a substituted or unsubstituted C1 to C5 alkyl group, for example, hydrogen, a methyl group, or an ethyl group, but are not limited thereto.

In Chemical Formula 4, Y² may be used without limitation as long as it is a monovalent cation. For example, Y² is a monovalent cation including a nitrogen atom, and may be, for example, a pyridinium ion or an ammonium ion, but is not limited thereto.

In Chemical Formula 2 and Chemical Formula 4, n is the number of Y¹ or Y², and is 1 or 2, but is not limited thereto.

In some example embodiments, the polymer may further include a structural unit represented by Chemical Formula 7 in addition to the structural unit represented by Chemical Formula 1 or Chemical Formula 2.

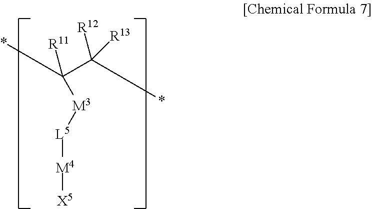

In Chemical Formula 7,
R¹¹ to R¹³ are each independently hydrogen, deuterium, or a substituted or unsubstituted C1 to C10 alkyl group,
M³ and M⁴ are each independently a single bond (e.g., a single covalent bond), —O—, —S—, —S(═O)—, —S(═O)₂—, —C(═O)—, —(CO)O—, —O(CO)O—, —NR^{a}— (wherein, R^{a} is hydrogen, deuterium, or a C1 to C10 alkyl group), or a combination thereof,
L⁵ is a single bond (e.g., a single covalent bond), a substituted or unsubstituted C1 to C10 alkylene group, a substituted or unsubstituted C2 to C10 alkenylene group, a substituted or unsubstituted C1 to C10 heteroalkylene group, a substituted or unsubstituted C3 to C20 cycloalkylene group, a substituted or unsubstituted C6 to C20 arylene group, or a combination thereof, and
X⁵ is hydrogen, deuterium, a hydroxy group, a substituted or unsubstituted C1 to C10 alkyl group, a substituted or unsubstituted C2 to C10 alkenyl group, a substituted or unsubstituted C2 to C10 alkynyl group, a substituted or unsubstituted C1 to C10 heteroalkyl group, a substituted or unsubstituted C3 to C20 cycloalkyl group, a substituted or unsubstituted C2 to C20 heterocycloalkyl group, or a substituted or unsubstituted C6 to C20 aryl group.

In some example embodiments, the polymer may be represented by any one or more selected from among Chemical Formula 5-1 to Chemical Formula 5-4:

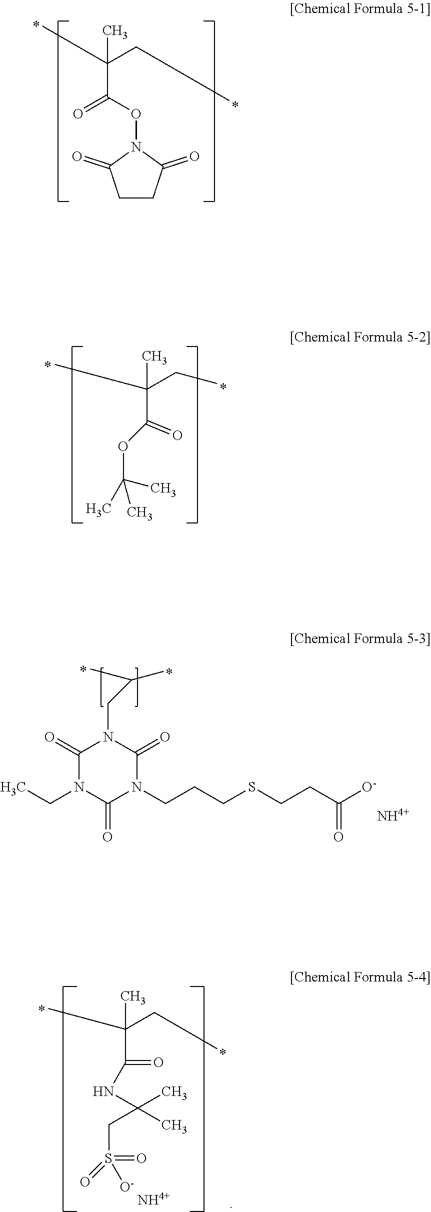

In some example embodiments, the compound may be represented by any one or more selected from among Chemical Formula 6-1 to Chemical Formula 6-5:

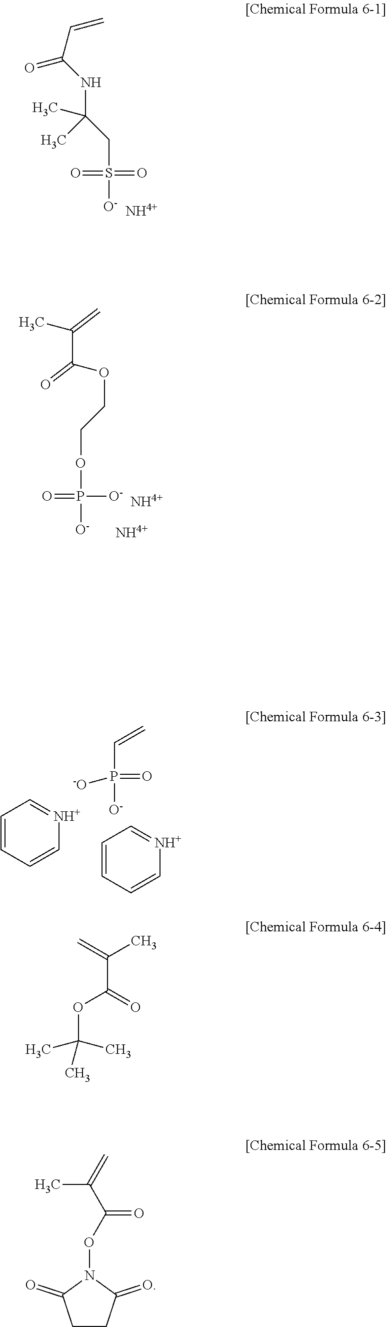

The polymer included in the composition according to some example embodiments may have a weight average molecular weight of about 1,000 g/mol to about 300,000 g/mol, for example, about 1,000 g/mol to about 200,000 g/mol, for example, about 1,000 g/mol to about 100,000 g/mol, for example, about 2,000 g/mol to about 90,000 g/mol, for example, about 2,000 g/mol to about 70,000 g/mol, for example, about 2,000 g/mol to about 50,000 g/mol, for example, about 5,000 g/mol to about 50,000 g/mol, or, for example, about 5,000 g/mol to about 30,000 g/mol, but is not limited thereto. By having a weight average molecular weight within the above ranges, a carbon content and solubility in the solvent of the resist underlayer composition including the polymer may be adjusted and optimized or enhanced.

The polymer may be included in an amount of about 0.05 wt % to about 50 wt % based on a total weight of the resist underlayer composition. In embodiments, the polymer may be included in an amount of about 0.05 wt % to about 40 wt %, for example, about 0.05 wt % to about 30 wt %, or, for example, about 0.1 wt % to about 30 wt %, based on a total weight of the resist underlayer composition, but is not limited thereto. By including the polymer within the above ranges in the composition, the thickness, surface roughness, and a degree of planarization of the resist underlayer may be adjusted and enhanced.

The structural unit represented by Chemical Formula 1 or Chemical Formula 2 may be included in an amount of about 5.0 wt % to about 80 wt % based on a total weight of the polymer. For example, the structural unit represented by Chemical Formula 1 or Chemical Formula 2 may be included in an amount of about 5.0 wt % to about 75 wt %, for example, about 5.0 wt % to about 70 wt %, for example, about 5.0 wt % to about 65 wt %, for example, about 5.0 wt % to about 60 wt %, for example, about 10 wt % to about 80 wt %, for example, about 10 wt % to about 70 wt %, for example, about 15 wt % to about 70 wt %, for example, about 20 wt % to about 70 wt %, or, for example, about 25 wt % to about 70 wt % based on a total weight of the polymer, but is not limited thereto. If the polymer includes the structural unit represented by Chemical Formula 1 or Chemical Formula 2 within the above ranges, the adhesion between the composition and the photoresist can be further improved or enhanced.

The compound may have a molecular weight of about 100 g/mol to about 2,000 g/mol, for example, about 100 g/mol to about 1,000 g/mol, for example, about 100 g/mol to about 900 g/mol, for example, about 100 g/mol to about 80 g/mol, for example, about 100 g/mol to about 700 g/mol, or, for example, about 100 g/mol to about 600 g/mol, but is not limited thereto. Because the compound has a molecular weight in the above ranges, the carbon content and solubility in the solvent of the resist underlayer composition including the compound can be adjusted and optimized or enhanced.

The compound represented Chemical Formula 3 or Chemical Formula 4 may be included in an amount of about 0.01 wt % to about 20 wt % based on a total weight of the resist underlayer composition. For example, the compound may be included in an amount of about 0.01 wt % to about 10 wt %, for example, about 0.02 wt % to about 5 wt %, or, for example, about 0.02 wt % to about 2 wt %, but is not limited thereto. By including the compound in the above ranges, the adhesion between the composition and the photoresist can be further improved or enhanced.

The resist underlayer composition according to some example embodiments may include a solvent. The solvent is not particularly limited as long as it has sufficient solubility and/or dispersibility for the polymer and compound according to some example embodiments, but may be, for example, propylene glycol, propylene glycol diacetate, methoxypropanediol, diethylene glycol, diethylene glycol butylether, tri(ethylene glycol)monomethylether, propylene glycol monomethylether, propylene glycol monomethylether acetate (PGMEA), cyclohexanone, ethyllactate, gamma-butyrolactone, N,N-dimethyl formamide, N,N-dimethyl acetamide, methylpyrrolidone, methylpyrrolidinone, methyl 2-hydroxyisobutyrate, acetylacetone, ethyl 3-ethoxypropionate, or a combination thereof.

The resist underlayer composition according to some example embodiments may further include one or more polymers selected from among an acrylic resin, an epoxy resin, a novolac-based resin, a glycoluril-based resin, and a melamine-based resin, in addition to the polymer and solvent, but is not limited thereto.

The resist underlayer composition according to some example embodiments may further include an additive including a surfactant, a photoacid generator, a thermal acid generator, a plasticizer, or a combination thereof.

The surfactant may be used to improve coating defects caused by an increase in a solid content if (e.g., when) forming the resist underlayer, and may be, for example, an alkylbenzenesulfonate salt, an alkylpyridinium salt, polyethylene glycol, a quaternary ammonium salt, and/or the like, but is not limited thereto.

The thermal acid generator may be an acidic compound such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carbonic acid, or/and benzointosylate, 2-nitrobenzyltosylate, and/or other organic sulfonic acid alkylester may be used, but is not limited thereto.

The plasticizer is not particularly limited, and a variety of suitable plasticizers generally used in the art may be used. Examples of a plasticizer may include low molecular compounds (e.g., low molecular weight compounds) such as phthalic acid esters, adipic acid esters, phosphoric acid esters, trimellitic acid esters, citric acid esters, and/or the like, polyether compounds, polyester-based compounds, polyacetal compounds, and/or the like.

The additive may be included in an amount of about 0.0001 to about 40 parts by weight based on 100 parts by weight of the resist underlayer composition. Within the foregoing ranges, solubility may be improved or enhanced while optical properties of the resist underlayer composition are not (or substantially not) changed.

According to some example embodiments, a resist underlayer manufactured using the aforementioned resist underlayer composition is provided. The resist underlayer may be formed by coating the aforementioned resist underlayer composition on, for example, a substrate and then curing through a heat treatment process.

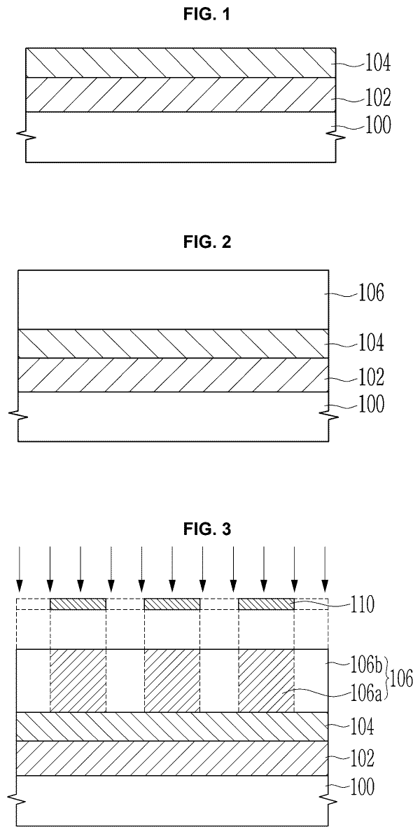

Hereinafter, a method of forming a pattern using the aforementioned resist underlayer composition is described with reference to FIGS. 1-6. FIGS. 1-6 are cross-sectional views illustrating a method of forming a pattern using the resist underlayer composition according to embodiments of the present disclosure.

Referring to FIG. 1, an etching target is prepared. The etching target may be a thin film 102 formed on a semiconductor substrate 100. Hereinafter, the etching target is limited to the thin film 102. An entire surface of the thin film 102 is washed to remove impurities and/or the like remaining thereon. The thin film 102 may be or include, for example, a silicon nitride layer, a polysilicon layer, and/or a silicon oxide layer.

Subsequently, the aforementioned resist underlayer composition is coated on the surface of the cleaned thin film 102 by utilizing a spin coating method.

Then, the coated composition is dried and baked to form a resist underlayer 104 on the thin film 102. For example, a first baking process may be performed at a temperature of about 100° C. to about 500° C., or, for example, about 100° C. to about 300° C. For example, the resist underlayer composition is described above in more detail and thus duplicative description thereof will not be repeated here.

Referring to FIG. 2, a photoresist film 106 is formed by coating a photoresist on the resist underlayer 104. In some example embodiments, the photoresist composition for forming the photoresist film 106 may include an organometallic compound, a solvent, etc., but is not limited thereto.

Referring to FIG. 3, the photoresist film 106 may be selectively exposed. Exposure of the photoresist film 106 may be, for example, performed by positioning an exposure mask 110 having a set or predetermined pattern on a mask stage of an exposure apparatus and aligning the exposure mask 110 on the photoresist film 106. Subsequently, light may be irradiated into (e.g., through) the exposure mask such that a set or predetermined region of the photoresist film 106 formed on the substrate 100 may react (e.g., selectively reacts) with light passing (e.g., through) the exposure mask 110 (e.g., by light originally irradiated into (e.g., through) the exposure mask 110).

For example, the light used during the exposure may include electromagnetic radiation selected from among short wavelength light such as an i-line having a wavelength of 365 nanometer (nm), a KrF excimer laser having a wavelength of 248 nm, and/or an ArF excimer laser having a wavelength of 193 nm. In embodiments, EUV (extreme ultraviolet) having a wavelength of 13.5 nm (e.g., corresponding to extreme ultraviolet light) may be used.

The exposed region 106b of the photoresist film 106 has a different solubility from the unexposed region 106a of the photoresist film 106 as a polymer is formed through a crosslinking reaction such as condensation (e.g., a condensation reaction) between organometallic compounds.

Subsequently, a second baking process is performed on the substrate 100. The second baking process may be performed at a temperature of about 90° C. to about 200° C. By performing the second baking process, the exposed region 106b of the photoresist film 106 becomes difficult to dissolve in the developer.

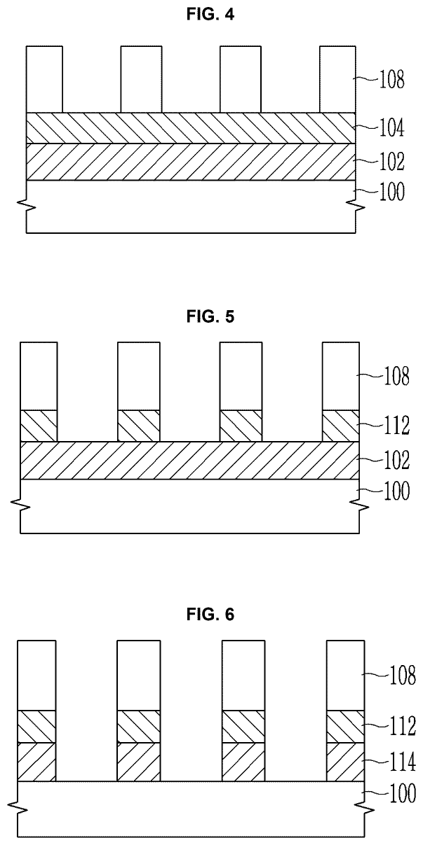

Referring to FIG. 4, the photoresist film 106a corresponding to the unexposed region is dissolved and removed using an organic solvent developer such as 2-heptanone, and thereby the photoresist film 106b remaining after development forms the photoresist pattern 108.

As described above, the developer used in the method of forming a pattern according to some example embodiments may be an organic solvent. Examples of organic solvents used in the method of forming a pattern according to some example embodiments may include ketones such as methyl ethyl ketone, acetone, cyclohexanone, and/or 2-heptanone, alcohols such as 4-methyl-2-propanol, 1-butanol, isopropanol, and/or 1-propanol, methanol, esters such as propylene glycol monomethyl ether acetate, ethyl acetate, ethyl lactate, n-butyl acetate, and/or butyrolactone, aromatic compounds such as benzene, xylene, and/or toluene, or a combination thereof.

However, the photoresist pattern according to some example embodiments is not necessarily limited to being formed as a negative tone image, and may be formed to have a positive tone image. In embodiments, the developer that can be used to form a positive tone image may be a quaternary ammonium hydroxide composition such as tetraethylammonium hydroxide, tetrapropylammonium hydroxide, tetrabutylammonium hydroxide, or a combination thereof.

As explained elsewhere herein, the photoresist pattern 108 formed by exposure to high-energy light such as not only light with wavelengths such as i-line (wavelength: 365 nm), KrF excimer laser (wavelength: 248 nm), and/or ArF excimer laser (wavelength: 193 nm), but also EUV (Extreme UltraViolet; wavelength: 13.5 nm) or an E-Beam may have a width of about 5 nm to about 100 nm thick. For example, the photoresist pattern 108 may be formed to have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In embodiments, the photoresist pattern 108 may have a pitch having a half-pitch of less than or equal to about 50 nm, for example, less than or equal to about 40 nm, for example, less than or equal to about 30 nm, for example, less than or equal to about 20 nm, or, for example, less than or equal to about 10 nm and a line width roughness of less than or equal to about 5 nm, less than or equal to about 3 nm, less than or equal to about 2 nm, or less than or equal to about 1 nm.

Subsequently, the resist underlayer 104 is etched using the photoresist pattern 108 as an etch mask. An organic film pattern 112 as shown in FIG. 5 is formed through the above etching process.

The formed organic film pattern 112 may also have a width corresponding to the photoresist pattern 108. The etching may be, for example, dry etching using etching gas, and the etching gas may be, for example, CHF₃, CF₄, Cl₂, O₂, and/or a mixed gas thereof. As described above, because the resist underlayer formed by the resist underlayer composition according to the embodiment has a fast etch rate, a smooth etching process may be performed within a short time.

Referring to FIG. 6, the photoresist pattern 108 is applied as an etching mask to etch the exposed thin film 102. As a result, the thin film is formed into a thin film pattern 114.

In the exposure process performed previously, a thin film pattern 114 formed by an exposure process performed using a short wavelength light source such as an i-line (a wavelength of 365 nm), a KrF excimer laser (a wavelength of 248 nm), and/or an ArF excimer laser (a wavelength of 193 nm) may have a width of tens to hundreds of nm, and the thin film pattern 114 formed by the exposure process performed using the EUV light source may have a width of less than or equal to about 20 nm.

Hereinafter, embodiments of the present disclosure are described in more detail through Examples regarding synthesis of the polymer and preparation of a resist underlayer composition including the same. However, the present disclosure is technically not restricted by the following examples.

### SYNTHESIS OF POLYMERS

### Synthesis Example 1

54 g of PGMEA, 8.5 g of tert-butyl methacrylate, 12.9 g of 2-(methacryloyloxy)ethyl acetoacetate, 7.8 g of 2-hydroxyethyl methacrylate and 5.9 g of AIBN (azobisisobutyronitrile) are added to a 120 ml bottle and then, mixed at room temperature (25° C.). 20 g of PGMEA is added to a 250 mL 3-necked round flask, and after connecting a condenser thereto, an internal temperature of the flask is increased to 90° C. Subsequently, the resultant mixed solution is slowly added to the 3-necked flask maintained at 90° C. for 1 hour, while stirring, and then, reacted for 3 hours and cooled to room temperature. The resultant reaction solution is dropped to a 1 L wide mouth bottle including 700 g of heptane to produce gum, which is then dissolved in 50 g of PGMEA. The resultant dissolved resin solution is treated with heptane to once more form precipitates and remove monomolecules (e.g., monomers) and low molecule (e.g., low molecular weight compounds), thereby finally obtaining a polymer (a weight average molecular weight (Mw): 7,000 g/mol) composed of structural units represented by Chemical Formulas 1a to 1c. The polymer includes the structural units represented by Chemical Formulas 1a to 1c respectively in an amount of 44 mol %, 28 mol %, and 28 mol % based on total moles of the structural units.

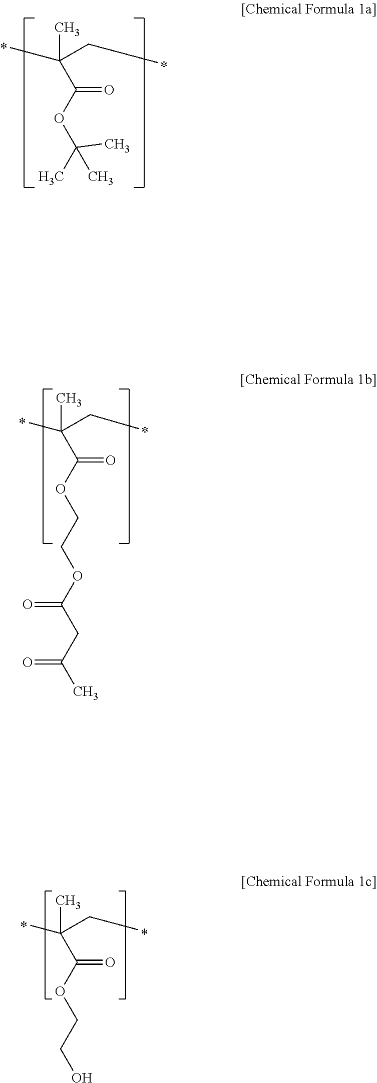

### Synthesis Example 2

58 g of PGMEA, 10 g of N-succinimidyl methacrylate, 14 g of butyl acrylate, 7.2 g of 2-hydroxyethyl methacrylate, and 5.4 g of AIBN (azobisisobutyronitrile) are added to a 120 ml bottle and then, mixed at room temperature. 20 g of PGMEA is added to a 250 mL 3-necked round flask, and after connecting a condenser thereto, an internal temperature of the flask is increased to 90° C. Subsequently, the resultant mixed solution is slowly added to the 3-neck flask maintained at 90° C. for 1 hour, while stirring, and then, reacted for 3 hours and cooled to room temperature. The resultant reaction solution is dropped to a 1 L wide mouth bottle including 700 g of heptane to produce gum, which is then dissolved in 50 g of PGMEA. The resultant dissolved resin solution is treated with heptane to once more form precipitates and remove monomolecules (e.g., monomers) and low molecules (e.g., low molecular weight compounds), thereby finally obtaining a polymer (a weight average molecular weight (Mw): 6,000 g/mol) composed of structural units represented by Chemical Formulas 2a to 2c. The polymer includes the structural units represented by Chemical Formulas 2a to 2c in each amount of 28 mol %, 48 mol %, and 28 mol % based on total moles of the structural units.

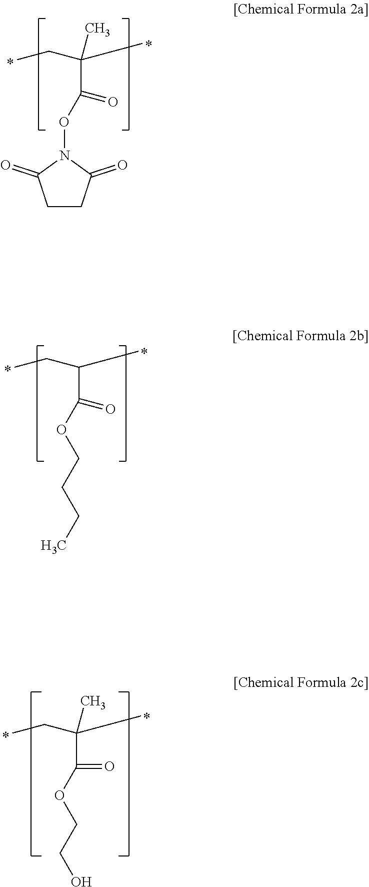

### Synthesis Example 3

24.9 g of 1,3,5-triallyl-1,3,5-triazinane-2,4,6-trione, 10 g of 3-mercaptoproponic acid, 0.8 g of AIBN (azobisisobutyronitrile), and 45 g of PGMEA are added to a 250 ml 3-necked round flask where a condenser is connected and then mixed at 75° C. for 10 hours. 13 g of butyl methacrylate, 13 g of 2-hydroxyethyl methacrylate, 5 g of AIBN (azobisisobutyronitrile), and 25 g of PGMEA are added to a 120 ml bottle and then mixed for 3 hours. Subsequently, the resultant mixed solution is slowly added to the 250 mL 3-necked round flask, reacted for 10 hours, and cooled to room temperature. The resultant reaction solution is dropped to a 1 L wide bottle including 700 g of heptane to produce gum, which is then dissolved in 50 g of PGMEA. The resultant dissolved resin solution is treated with heptane to once more form precipitates and remove monomolecules (e.g., monomers) and low molecules (e.g., low molecular weight compounds) and then, mixed with 10 g of ammonia water, and the obtained mixture is stirred at room temperature for 20 hours and concentrated to remove water and residual ammonia to obtain a polymer (a weight average molecular weight (Mw): 9,000 g/mol) composed of structural units represented by Chemical Formulas 3a to 3c. The polymer includes structural units represented by Chemical Formulas 3a to 3c in each amount of 33 mol %, 33 mol %, and 34 mol % based on total moles of the structural units.

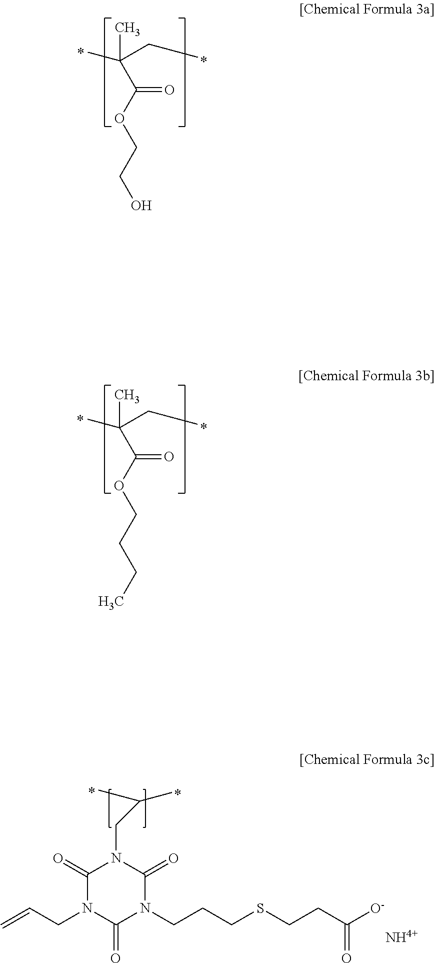

### Synthesis Example 4

47 g of PGMEA, 10 g of glycidyl methacrylate, 15 g of 2-(methacryloyloxy)ethyl acetoacetate, and 8 g of AIBN (azobisisobutyronitrile) are added to a 120 ml bottle and then, mixed at room temperature. 15 g of PGMEA is added to a 250 mL 3-necked round flask, and after connecting a condenser thereto, an internal temperature of the flask is increased to 90° C. Subsequently, the resultant mixed solution is slowly added to the 3-neck flask maintained at 80° C. for 1 hour, while stirring, and then, reacted for 3 hours and cooled to room temperature. The resultant reaction solution is dropped to a 1 L wide mouth bottle including 700 g of heptane to produce gum, which is then dissolved in 50 g of PGMEA. The dissolved resin solution is treated with heptane to once more form precipitates and remove monomolecules (e.g., monomers) and low molecules (e.g., low molecular weight compounds), thereby finally obtaining a polymer (a weight average molecular weight (Mw): 8,000 g/mol) composed of structural units represented by Chemical Formulas 4a and 4b. The polymer includes the structural units represented by Chemical Formulas 4a and 4b in each amount of 50 mol % and 50 mol % based on total moles of the structural units.

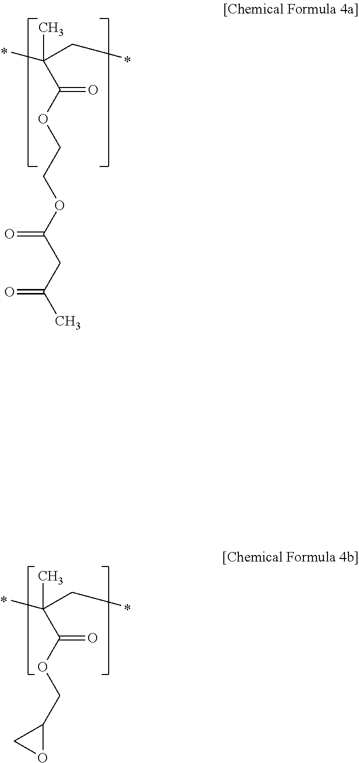

### Synthesis Example 5

38 g of 1,3,5-triallyl-1,3,5-triazinane-2,4,6-trione and 57 g of PGMEA are added to a 250 ml 3-necked round flask, and a condenser is connected thereto. After increasing a flask temperature to 80° C., a solution prepared by mixing 7 g of 5-mercaptopropanol and 1 g of AIBN (azobisisobutyronitrile) in 12 g of PGMEA in a 120 mL bottle is slowly added thereto for 1 hour and then, reacted for 5 hours and cooled to room temperature. The resultant reaction solution is dropped to a 1 L wide mouth bottle including 700 g of heptane to produce gum, which is then dissolved in 50 g of PGMEA. The resultant dissolved resin solution is treated with heptane to once more form precipitates and remove monomolecules (e.g., monomers) and low molecules (e.g., low molecular weight compounds), thereby finally obtaining a polymer (a weight average molecular weight (Mw): 10,000 g/mol) composed of structural units represented by Chemical Formulas 5a and 5b. The polymer includes the structural units represented by Chemical Formulas 5a and 5b in each amount of 50 mol % and 50 mol % based on total moles of the structural units.

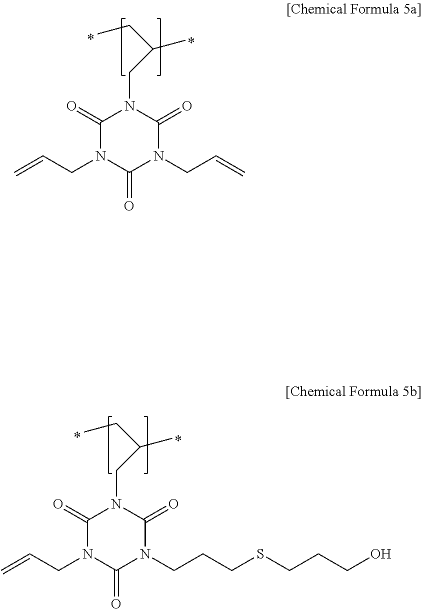

### Synthesis Example 6

38 g of 1,3,5-triallyl-1,3,5-triazinane-2,4,6-trione and 57 g of PGMEA are added to a 250 ml 3-necked round flask, and a condenser is connected thereto. After increasing a flask temperature to 80° C., a solution prepared by mixing 12 g of 3-mercaptoproponic acid, 1 g of AIBN (azobisisobutyronitrile), and 12 g of PGMEA in a 120 ml bottle is slowly added thereto for 1 hour and then, reacted for 5 hours and cooled to room temperature. The resultant reaction solution is dropped into a 1 L wide mouth bottle including 700 g of heptane to produce gum, which is then dissolved in 50 g of PGMEA. The dissolved resin solution is treated with heptane to once more produce precipitates and remove monomolecules (e.g., monomers) and low molecules (e.g., low molecular weight compounds), thereby finally obtaining a polymer (a weight average molecular weight: 4,000 g/mol) composed of a structural unit represented by Chemical Formula 6a.

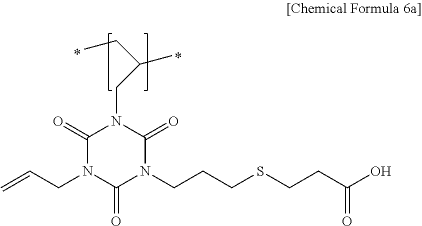

### Synthesis Example 7

20 g of 2-acrylamido-2-methyl-1-propanesulfonic acid and 24 g of aqueous ammonia are added to a 100 mL round flask and stirred at room temperature for 24 hours, and then, the resultant residue after a reaction is all concentrated and removed by using an evaporator, finally obtaining a compound represented by Chemical Formula A.

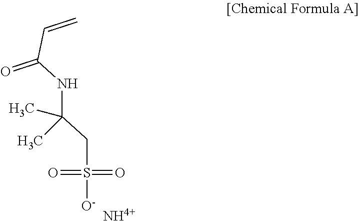

### Synthesis Example 8

11 g of vinylphosphonic acid and 18 g of pyridine are added to a 100 mL round flask and stirred at room temperature for 24 hours, and then, the residue after a reaction is all concentrated and removed, finally obtaining a compound represented by Chemical Formula B.

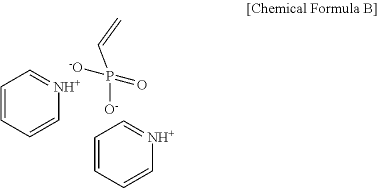

### Preparation of Resist Underlayer Compositions

### Example 1

Each of the polymers according to Synthesis Examples 1 to 6, each compound represented by Chemical Formulas A to E, a crosslinking agent (PD1174, TCI Corp.), and a thermal acid generator (TAG) (pyridinium p-toluenesulfonate (PPTS)) are each dissolved in PGMEA to a solid concentration of 3 wt %. Subsequently, the solutions are diluted with methyl 2-hydroxyisobutyrate to prepare each resist underlayer composition having a solid concentration of 1 wt % based on a total amount of the composition as shown in Table 1. Each content shown in Table 1 uses wt % based on a total weight of the resist underlayer composition.

TABLE 1

| | Polymer | Compound | Crosslinking | |
|---|---|---|---|---|
| | (wt %) | (wt %) | agent | TAG |
| Example 1 | Synthesis Example 1 | — | 0.16 | 0.04 |
| | (0.80) | | | |
| Example 2 | Synthesis Example 2 | — | 0.16 | 0.04 |
| | (0.80) | | | |
| Example 3 | Synthesis Example 3 | — | 0.16 | 0.04 |
| | (0.80) | | | |
| Example 4 | Synthesis Example 4 | Chemical Formula A | 0.16 | 0.04 |
| | (0.56) | (0.24) | | |
| Example 5 | Synthesis Example 4 | Chemical Formula B | 0.16 | 0.04 |
| | (0.56) | (0.24) | | |
| Example 6 | Synthesis Example 5 | Chemical Formula A | 0.16 | 0.04 |
| | (0.56) | (0.24) | | |
| Example 7 | Synthesis Example 4 | Chemical Formula C | 0.16 | 0.04 |
| | (0.56) | (0.24) | | |
| Example 8 | Synthesis Example 5 | Chemical Formula D | 0.16 | 0.04 |
| | (0.56) | (0.24) | | |
| Comparative | Synthesis Example 6 | — | 0.16 | 0.04 |
| Example 1 | (0.80) | | | |
| Comparative | Synthesis Example 4 | Chemical Formula E | 0.16 | 0.04 |
| Example 2 | (0.64) | (0.16) | | |

In Table 1, the compounds represented by Chemical Formulas C to E used the following commercially available compounds.

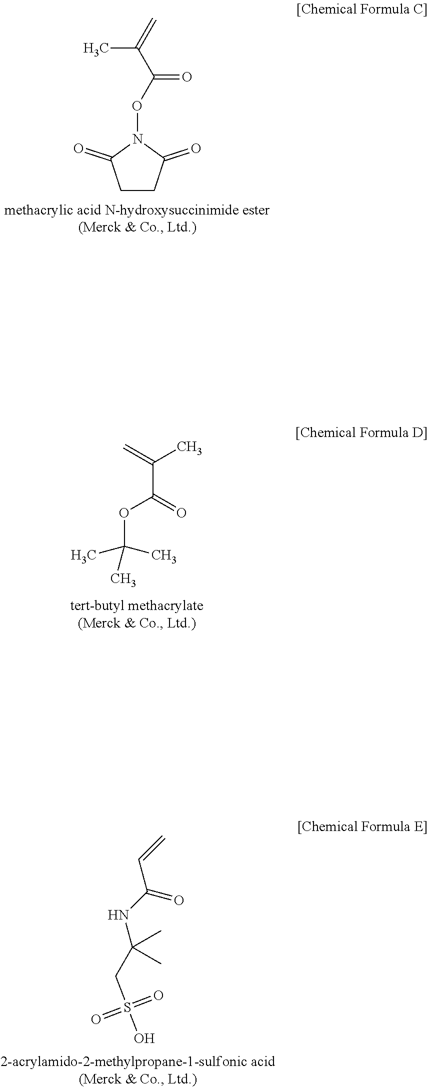

### Evaluation 1: Evaluation of Adhesion and Coating Property

Each of the resist underlayer compositions of the examples and the comparative examples was taken by 2 mL and coated on an 8-inch wafer at 1,500 rpm for 20 seconds by using a spin coater (Mikasa Co., Ltd.) and then, cured at 210° C. for 90 seconds to form a thin film (resist underlayer). The thin film was measured with respect to a contact angle by dropping distilled water (DIW) on the surface and also, surface roughness (Rq) by taking an image with an atomic force microscope (AFM) and using a software (Optical Profiler), and the results are shown in Table 2. Herein, the smaller contact angle, the better adhesion with a resist, and the smaller surface roughness, the better contacting properties of thin films.

TABLE 2

| | Contact angle (°) | Surface roughness (nm) |
|---|---|---|
| Example 1 | 50 | 0.25 |
| Example 2 | 53 | 0.30 |
| Example 3 | 55 | 0.27 |
| Example 4 | 55 | 0.22 |
| Example 5 | 51 | 0.23 |
| Example 6 | 53 | 0.28 |
| Example 7 | 54 | 0.25 |
| Example 8 | 52 | 0.28 |
| Comparative Example 1 | 65 | 0.73 |

Referring to Table 2, the resist underlayers formed of the resist underlayer compositions according to the Examples were confirmed to exhibit a smaller angle than the resist underlayers formed of the resist underlayer compositions according to the Comparative Examples. Accordingly, the resist underlayers formed of the resist underlayer compositions according to the Examples were confirmed to exhibit excellent adhesion with a photoresist, compared with the resist underlayers formed of the resist underlayer compositions according to the Comparative Examples. The resist underlayers formed of the resist underlayer compositions according to the Examples exhibited smaller surface roughness than those formed of the resist underlayer compositions according to the Comparative Examples, which confirmed that the resist underlayer compositions according to the Examples exhibited improved coating properties of thin films, compared with the resist underlayer compositions according to the Comparative Examples.

### Evaluation 2: Evaluation of Storage Stability

The resist underlayer compositions according to the examples and the comparative examples were stored at 35° C. for 1 month and then, examined with naked eyes (e.g., unassisted eyes) to check whether or not precipitates were produced after 1 month and thus evaluate storage stability. If no precipitates were formed, the storage stability was evaluated to be excellent, and the results are shown in Table 3.

TABLE 3

| | Precipitate |
|---|---|
| Example 1 | not generated |
| Example 2 | not generated |
| Example 3 | not generated |
| Example 4 | not generated |
| Example 5 | not generated |
| Example 6 | not generated |
| Example 7 | not generated |
| Example 8 | not generated |
| Comparative Example 1 | generated |
| Comparative Example 2 | generated |

Referring to Table 3, the resist underlayer compositions according to the Examples exhibited no precipitate formation after the 1 month's storage, but the resist underlayer compositions according to the Comparative Examples exhibited precipitate formation after 1 month of storage. Accordingly, the compositions of the Examples were confirmed to have excellent storage stability, compared with the compositions of the Comparative Examples.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

Hereinbefore, certain embodiments of the present disclosure have been described and illustrated, however, it should be apparent to a person having ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims, and equivalents thereof, of the present disclosure.

Description of Symbols

| | |
|---|---|
| 100: substrate | 102: thin film |
| 104: resist underlayer | 106: photoresist film |
| 106a: unexposed region | 106b: exposed region |
| 108: photoresist pattern | 110: mask |
| 112: organic film pattern | 114: thin film pattern |

What is claimed is:

1. A resist underlayer composition, comprising:
a polymer comprising a structural unit represented by Chemical Formula 1 or Chemical Formula 2, a compound represented Chemical Formula 3 or Chemical Formula 4, or a combination thereof, and a solvent: 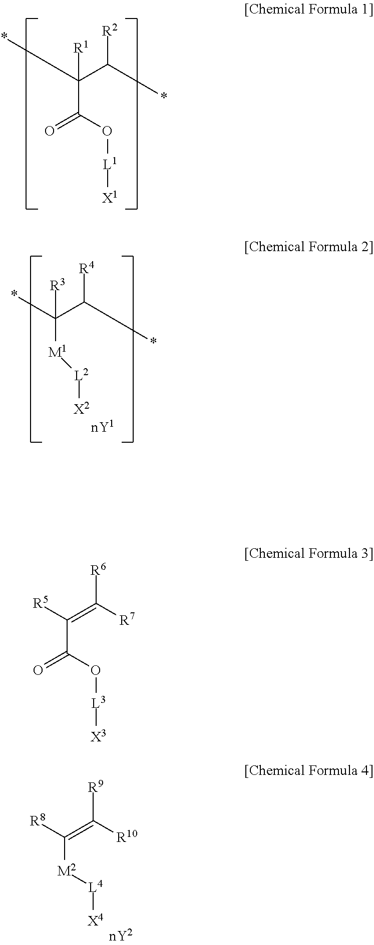
wherein, in Chemical Formula 1 to Chemical Formula 4,
R¹ to R¹⁰ are each independently hydrogen, deuterium, or a substituted or unsubstituted C1 to C10 alkyl group,
M¹ and M² are each independently a substituted or unsubstituted C1 to C10 alkylene group, —C(═O)NH—, —C(═O)—, —C(═O)O—, or a combination thereof,
L¹ to L⁴ are each independently a single bond, a substituted or unsubstituted C1 to C10 alkylene group, a substituted or unsubstituted C1 to C10 heteroalkylene group, a substituted or unsubstituted C2 to C10 heterocyclic group, or a combination thereof,
X¹ and X³ are each independently a substituted or unsubstituted C1 to C10 alkyl group, a substituted or unsubstituted C3 to C20 cycloalkyl group, or a substituted or unsubstituted C2 to C20 heterocycloalkyl group,
X² and X⁴ are each independently, —C(═O)O^{—}, —S(═O)₂O^{—}, —OP(═O)O₂^{—}, or —P(═O)O₂^{—},
Y¹ and Y² are each independently a monovalent cation, and
n is 1 or 2, indicating the number of Y¹ or Y².

2. The resist underlayer composition as claimed in claim 1, wherein in Chemical Formula 1, L¹ is a single bond, or a substituted or unsubstituted C1 to C5 alkylene group, X¹ is a substiuted or unsubstituted C1 to C5 alkyl group, a substituted or unsubstituted C3 to C10 cycloalkyl group, or a substituted or unsubstituted C2 to C10 heterocycloalkyl group.

3. The resist underlayer composition as claimed in claim 1, wherein in Chemical Formula 2, M¹ is a substituted or unsubstituted C1 to C5 alkylene group, —C(═O)NH—, —C(═O)O—, or a combination thereof, and Y¹ is a monovalent cation comprising a nitrogen atom.

4. The resist underlayer composition as claimed in claim 1, wherein in Chemical Formula 3, L³ is a single bond, and X³ is a substituted or unsubstituted C1 to C10 alkyl group, or a substituted or unsubstituted C2 to C20 heterocycloalkyl group.

5. The resist underlayer composition as claimed in claim 1, wherein in Chemical Formula 4, M² is —C(═O)NH—, or —C(═O)O—, L⁴ is a single bond, or a substituted or unsubstituted C1 to C5 alkylene group, X⁴ is —S(═O)₂O^{—}, —OP(═O)O₂^{—}, or —P(═O)O₂^{—}, and Y² is a monovalent cation including a nitrogen atom.

6. The resist underlayer composition as claimed in claim 1, wherein the polymer is represented by one or more selected from among Chemical Formula 5-1 to Chemical Formula 5-4:

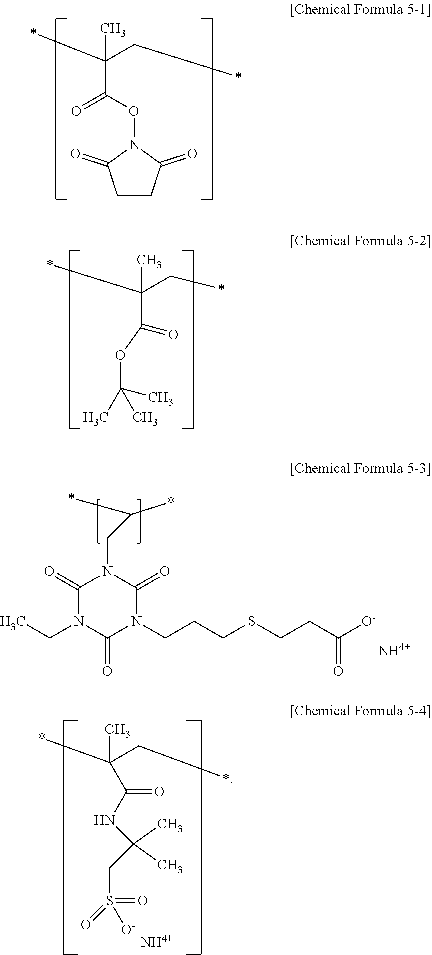

7. The resist underlayer composition as claimed in claim 1, wherein the compound is represented by one or more selected from among Chemical Formula 6-1 to Chemical Formula 6-5:

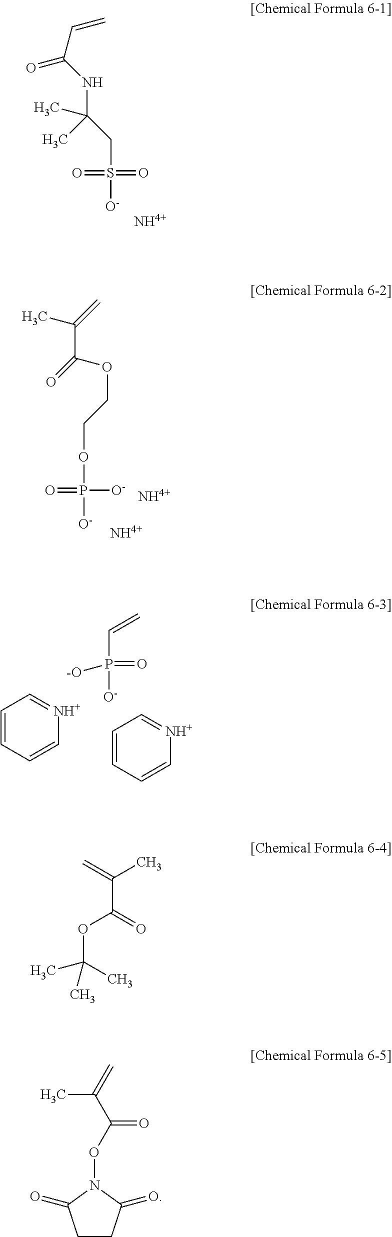

8. The resist underlayer composition as claimed in claim 1, wherein a weight average molecular weight of the polymer is about 1,000 g/mol to about 300,000 g/mol.

9. The resist underlayer composition as claimed in claim 1, wherein the structural unit represented by Chemical Formula 1 or Chemical Formula 2 is included in an amount of about 5.0 wt % to about 80 wt % based on a total weight of the polymer.

10. The resist underlayer composition as claimed in claim 1, wherein the polymer is included in an amount of about 0.05 wt % to about 50 wt % based on a total weight of the resist underlayer composition.

11. The resist underlayer composition as claimed in claim 1, wherein a molecular weight of the compound is about 100 g/mol to about 1,000 g/mol.

12. The resist underlayer composition as claimed in claim 1, wherein the compound is included in an amount of about 0.01 wt % to about 20 wt % based on a total weight of the resist underlayer composition.

13. The resist underlayer composition as claimed in claim 1, wherein the composition further comprises one or more polymers selected from an acrylic resin, an epoxy resin, a novolac-based resin, a glycoluril-based resin, and a melamine-based resin.

14. The resist underlayer composition as claimed in claim 1, wherein the composition further comprises an additive of a surfactant, a thermal acid generator, a photoacid generator, a plasticizer, or a combination thereof.

15. A method of forming a pattern, the method comprising:
forming an etching target layer on a substrate,
forming a resist underlayer by applying the resist underlayer composition as claimed in claim 1 on the etching target layer,
forming a photoresist pattem on the resist underlayer, and
sequentially etching the resist underlayer and the etching target layer using the photoresist pattern as an etching mask.
